(19) United States
(12) Patent Application Publication
(10) Pub. No.: US 2015/0083041 A1
(43) Pub. Date: Mar. 26, 2015

(54) GLUE APPLICATOR

(71) Applicants: FU DING ELECTRONICAL TECHNOLOGY (JIASHAN) CO.,LTD., Zhejiang (CN); HON HAI PRECISION INDUSTRY CO., LTD., New Taipei (TW)

(72) Inventors: MING-LU YANG, New Taipei (TW); JIE NI, Jiashan (CN)

(21) Appl. No.: 14/490,050

(22) Filed: Sep. 18, 2014

(30) Foreign Application Priority Data
Sep. 25, 2013 (CN) 201320591764.3

(51) Int. Cl. B32B 37/12; C09J 5/00

(52) U.S. Cl. CPC B32B 37/1284; C09J 5/00; H05K 3/305
USPC 118/319

(57) ABSTRACT

A glue applicator includes a bracket, a driving assembly assembled to the bracket, and a positioning assembly. The positioning assembly includes a tray connected to the driving assembly, and a plurality of positioning blocks assembled to the tray and configured to fasten a glue dispenser to the tray. The tray can rotate relative to the bracket when driven by the driving assembly, and the glue dispenser can rotate along the tray. The present disclosure can improve the adhesion strength of glue.

### FIELD

The subject matter herein generally relates to a glue applicator.

### BACKGROUND

Sometimes, two elements of an electronic device need to be adhered together during assembly. In a typical glue coating process, a workman dispenses the glue from a glue dispenser, and coats the glue on elements. Then the two elements can be firmly adhered together.

### BRIEF DESCRIPTION OF THE DRAWINGS

Implementations of the present technology will now be described, by way of example only, with reference to the attached figures.

FIG. 1 is a perspective view of an embodiment of a glue applicator.

FIG. 2 is an exploded, perspective view of the glue applicator of FIG. 1.

FIG. 3 is a cross-sectional, perspective view of the glue applicator of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a glue applicator.

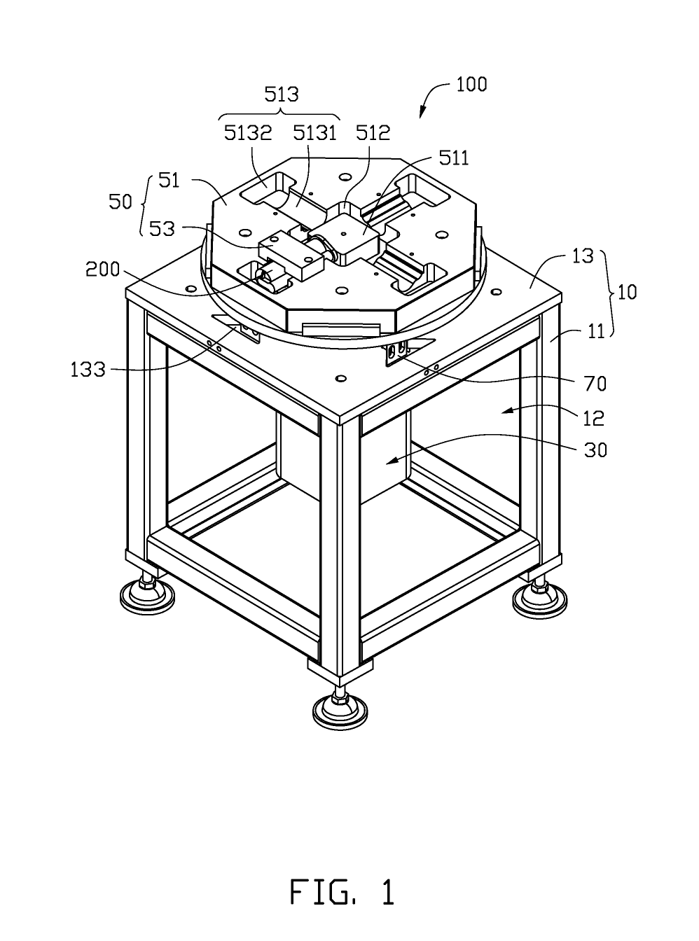

FIG. 1 illustrates an embodiment of a glue applicator. The glue applicator 100 is configured to rotate a glue dispenser 200, to separate the bubbles from the glue. The glue applicator 100 can include a bracket 10, a driving assembly 30, a positioning assembly 50, and four supporting assemblies 70. The driving assembly 30 can be installed on the bracket 10. The positioning assembly 50 can be connected to the driving assembly 30. The glue dispenser 200 can be attached to the positioning assembly 50. The driving assembly 30 can drive the positioning assembly 50 to rotate relative to the bracket 10. The four supporting assemblies 70 can be respectively assembled to the bracket 10, and resist against the positioning assembly 50. The four supporting assemblies 70 can be configured to support the positioning assembly 50. In at least one embodiment, the supporting assemblies can be less than, or more than four.

The positioning assembly 50 can include a tray 51 and four positioning blocks 53. The tray 51 can include a limiting block 511, a receiving groove 512 surrounding the limiting block 511, and four recesses 513 surrounding the receiving groove 512. The four recesses 513 can be respectively connected to the receiving groove 512. Each recess 513 can include a first portion 5131 and a second portion 5132, and the first portion 5131 can be positioned between the receiving groove 512 and the second portion 5132. The glue dispenser 200 can be assembled in the first portion 5131, the bottom of the glue dispenser 200 can extend through the receiving groove 512 and resist against the limiting block 511. A nozzle of the glue dispenser 200 can be coupled to the second portion 5132. Each of the four positioning blocks 53 can cross the corresponding first portion 5131, and can be connected to the tray 51 by screws. The positioning blocks 53 can be coupled to the corresponding first portion 5131, which can be configured to fasten the glue dispenser 200 to the tray 51. In at least one embodiment, the positioning blocks and the recesses can be less than, or more than four.

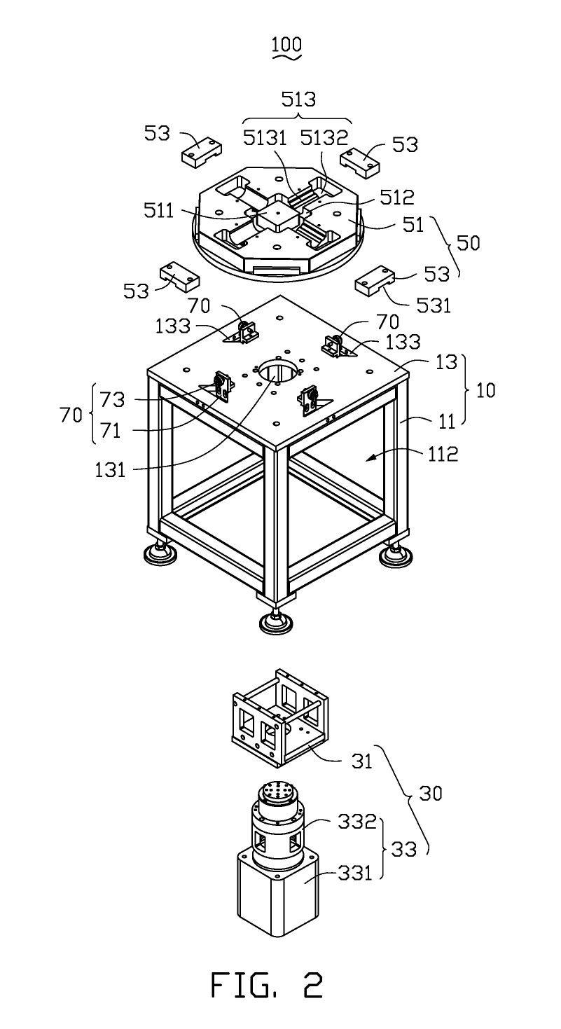

FIG. 2 illustrates an exploded, perspective view of the glue applicator. The bracket 10 can include a first bracket 11 and a mounting plate 13 assembled to the first bracket 11. The first bracket 11 can define a receiving portion 112. The mounting plate 13 can be substantially rectangular, and include a circular through hole 131 and four mounting holes 133 surrounding the through hole 131. The through hole 131 can be defined on a center of the mounting plate 13, and can be connected to the receiving portion 112. Four mounting holes 133 can be respectively located on the quarter lines of the circular through hole 131.

The driving assembly 30 can include a fixing bracket 31 and a driving member 33 assembled to the fixing bracket 31. The driving member 33 can include a main body 331 and a driving shaft 332 connected to the main body 331.

Each positioning block 53 can include a limiting slot 531 adjacent to the glue dispenser 200 (see FIG. 1). A part of the glue dispenser 200 can be locked in the limiting slot 531. The limiting slot 531 can be coupled to the corresponding first portion 5131, and the glue dispenser 200 can be clamped between the limiting slot 531 and the first portion 5131.

The four supporting assemblies 70 can be respectively assembled to the corresponding mounting hole 133 of the mounting plate 13, and include a second bracket 71 and a rotating wheel 73. The second bracket 71 can be assembled in the mounting hole 133, and part of second bracket 71 can extend beyond the mounting plate 13. The rotating wheel 73 can be rotatable and assembled to the second bracket 71, and resist the tray 51. When the tray 51 rotates relative to the bracket 10, the rotating wheel 73 can rotate relative to second bracket 71. The rotating wheel 73 can also be configured to support the tray 51, which can improve the stability of the tray 51.

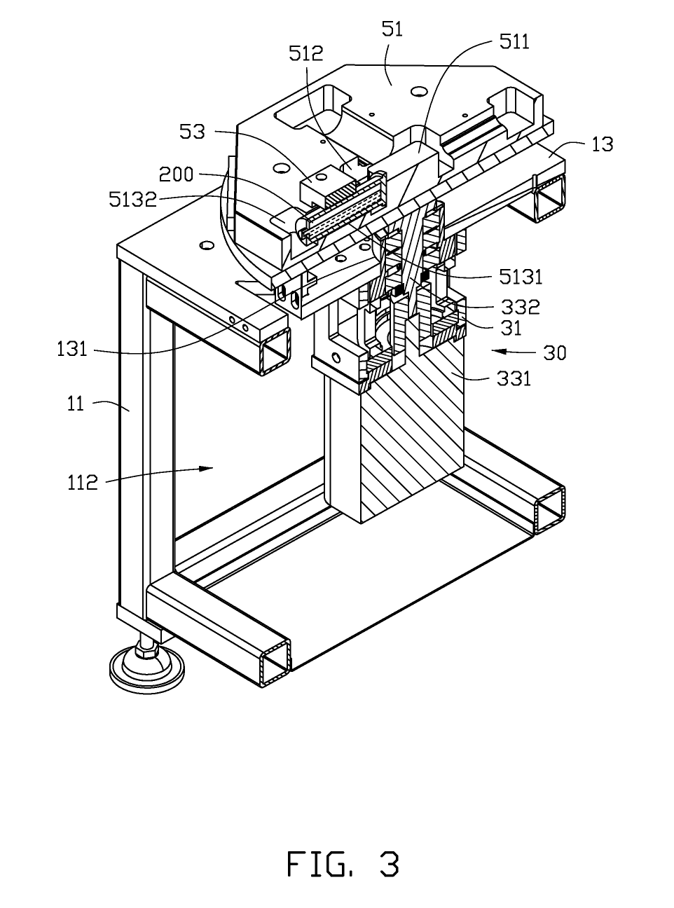

FIG. 3 illustrates a cross-sectional, perspective view of the glue applicator. The driving assembly 30 can be connected to the mounting plate 13. The fixing bracket 31 can be assembled on a bottom surface of the mounting plate 13, and received in the receiving portion 112. The driving member 33 can be assembled to the fixing bracket 31, and part of the driving member 33 can extend beyond the fixing bracket 31. The driving shaft 332 of the driving member 33 can pass through the through hole 131, and can be driven by the main body 331. Part of the driving shaft 332 can extend through the mounting plate 13, and can be connected to the tray 51.

In operation, the glue dispenser 200 can be assembled in the corresponding recess 513, and the nozzle of the glue dispenser 200 can be received in the second portion 5132 of the recess 513. The positioning block 53 can be attached to the tray 51, so the glue dispenser 200 can be firmly clamped between the recess 513 and the positioning block 53. The tray 51 can rotate driven by the main body 331, and create centrifugal force. The centrifugal force can move the glue to the nozzle of the glue dispenser 200, and the bubbles in the glue dispenser 200 move to the bottom of the glue dispenser 200.

The tray 51 can be rotated and form centrifugal force, the glue dispenser 200 can also rotate along with the tray 51. The bubbles can be separated from the glue in the glue dispenser 200 by centrifugal force. The glue emitted from the glue dispenser 200 is free of bubbles, which can improve the adhesion strength of the glue.

The embodiments shown and described above are only examples. Many details are often found in the art such as the other features of a glue applicator. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A glue applicator comprising:
a bracket;
a driving assembly connected to the bracket; and
a positioning assembly including:
a tray connected to the driving assembly, and
a plurality of positioning blocks connected to the tray;
wherein the tray and a glue dispenser are configured to rotate relative to the bracket when driven by the driving assembly.

2. The glue applicator as claimed in claim 1, wherein the glue applicator further comprises a plurality of supporting assemblies assembled to the bracket, and configured to support the positioning assembly.

3. The glue applicator as claimed in claim 2, wherein each supporting assembly comprises a second bracket assembled to the bracket and a rotating wheel being rotatable and assembled to the second bracket, the rotating wheel resists against the tray, the rotating wheel rotates relative to second bracket.

4. The glue applicator as claimed in claim 1, wherein the bracket comprises a first bracket and a mounting plate assembled to the first bracket.

5. The glue applicator as claimed in claim 4, wherein the driving assembly comprises a fixing bracket and a driving member assembled to the fixing bracket, the driving member is assembled on a bottom surface of the mounting plate, the driving member is assembled to the fixing bracket, and part of the driving member extends beyond the fixing bracket.

6. The glue applicator as claimed in claim 5, wherein the mounting plate comprises a circular through hole, the driving member comprises a main body and a driving shaft connected to the main body, the driving shaft passes through the through hole and connects to the tray.

7. The glue applicator as claimed in claim 1, wherein the mounting plate comprises a plurality of mounting holes surrounding the through hole, the plurality of mounting holes are respectively located on the quartering lines of the circular through hole.

8. The glue applicator as claimed in claim 1, wherein the tray comprises a limiting block, a receiving groove surrounding the limiting block, and a plurality of recesses surrounding the receiving groove, and the plurality of recesses are respectively connected to the receiving groove.

9. The glue applicator as claimed in claim 8, wherein each recess comprises a first portion and a second portion, the first portion is positioned between the receiving groove and the second portion, the glue dispenser is assembled in the first portion, the bottom of the glue dispenser extends through the receiving groove and resists against the limiting block, and a nozzle of the glue dispenser is coupled to the second portion.

10. The glue applicator as claimed in claim 1, wherein each positioning block comprises a limiting slot adjacent to the glue dispenser, and part of the glue dispenser is received in the limiting slot.
